(19) United States
(12) Patent Application Publication
(10) Pub. No.: US 2022/0334494 A1
(43) Pub. Date: Oct. 20, 2022

(54) PHOTOMASK CLAMPING DEVICE

(71) Applicant: CHANGXIN MEMORY TECHNOLOGIES, INC., Hefei City (CN)

(72) Inventor: Qingqing ZHAO, Hefei City (CN)

(73) Assignee: CHANGXIN MEMORY TECHNOLOGIES, INC., Hefei City (CN)

(21) Appl. No.: 17/647,457

(22) Filed: Jan. 8, 2022

Related U.S. Application Data
(63) Continuation of application No. PCT/CN2021/112259, filed on Aug. 12, 2021.

(30) Foreign Application Priority Data
Apr. 16, 2021 (CN) 202110414347.0

(51) Int. Cl. G03F 7/20; G03F 1/66

(52) U.S. Cl. CPC G03F 7/707; G03F 1/66; G03F 7/70758

(57) ABSTRACT

A photomask clamping device includes a clamping assembly, a frame body and a handle, where the clamping assembly is provided on the frame body, and is used to clamp a side of a photomask; a connecting portion is provided in the middle of one side of the frame body; the handle is rotatably connected to the connecting portion, and is provided with a first drive mechanism; and the first drive mechanism is connected to the connecting portion, and is used to drive the connecting portion to rotate. When it is necessary to deal with a problem on the surface of a photomask, the clamping assembly is used to clamp a side of the photomask, and the handle is held to take the photomask out of a container.

### CROSS-REFERENCE TO RELATED APPLICATIONS

This application is a continuation of International Patent Application No. PCT/CN2021/112259 filed on Aug. 12, 2021, which claims priority to Chinese Patent Application No. 202110414347.0 filed on Apr. 16, 2021. The disclosures of these applications are hereby incorporated by reference in their entirety.

### TECHNICAL FIELD

The present application relates to the technical field of semiconductor manufacturing, and in particular to a photomask clamping device.

### BACKGROUND

Generally, a photomask is placed above multiple sets of lenses inside a lithography device for exposure and other processes. In the semiconductor manufacturing process, static electricity is one of the important factors that damage the surface pattern of the photomask. The static electricity mainly comes from the air in the clean room or from the work clothes of the worker. In order to prevent the charge from being conducted to the photomask by the worker, a photomask clamping device is usually used to pick and place the photomask.

The photomask clamping device can be used to take a photomask out of a container when the photomask is treated in a darkroom. When it is necessary to deal with a problem on the surface of the photomask, the worker needs to flip the photomask clamping device together with the photomask, for example, by 180°, so as to flip the photomask from a glass surface to a pellicle surface. However, due to the limited operating space in the darkroom, it is inconvenient for the worker holding the photomask clamping device to rotate the wrist to adjust the position of the photomask, and the photomask is easily scratched.

### SUMMARY

The present application provides a photomask clamping device. The photomask clamping device includes a clamping assembly and a frame body, where the clamping assembly is provided on the frame body, and is used to clamp a side of a photomask; a connecting portion is provided in the middle of one side of the frame body; and a handle, where the handle is rotatably connected to the connecting portion, and is provided with a first drive mechanism; and the first drive mechanism is connected to the connecting portion, and is used to drive the connecting portion to rotate.

In the present application, when it is necessary to deal with a problem on the surface of a photomask, the clamping assembly is used to clamp a side of the photomask, and the handle is held to take the photomask out of a container. Then, with a central axis of the handle as a center of rotation, the first drive mechanism drives the connecting portion to rotate, thereby flipping the frame body and the photomask on the frame body from a glass surface to a pellicle surface. There is no need for a worker holding the handle to rotate the operator's wrist to flip the frame body and the photomask thereon. Therefore, it is convenient to adjust the flip position of the photomask. Under the drive action of the first drive mechanism, the frame body and the photomask are flipped stably, and the photomask is not easily scratched.

### BRIEF DESCRIPTION OF THE DRAWINGS

The drawings constituting part of the present application are provided for further understanding of the present application. The illustrative examples of the present application and description thereof are intended to explain the present application, rather than to constitute an improper limitation to the present application.

To describe the technical solutions in the embodiments of the present application more clearly, the drawings describing the embodiments are briefly described below. Apparently, the drawings described below are only some embodiments of the present application. Those of ordinary skill in the art may further obtain other drawings based on these drawings without creative efforts.

FIG. 1 is a view illustrating a structure of a photomask clamping device according to a first embodiment of the present application;

FIG. 2 is a view illustrating an internal structure of a handle of the photomask clamping device according to the first embodiment of the present application;

FIG. 3 is a view illustrating an internal structure of the handle of the photomask clamping device according to another embodiment of the present application;

FIG. 4 is a view illustrating a structure of the handle of the photomask clamping device according to a further embodiment of the present application;

FIG. 5 is a view illustrating an internal structure of the handle of the photomask clamping device according to a further embodiment of the present application;

FIG. 6 is a view illustrating a clamping portion of the photomask clamping device in a position of clamping a photomask according to the one embodiment of the present application;

FIG. 7 is a view illustrating the clamping portion of the photomask clamping device in a position of releasing the photomask according to the one embodiment of the present application;

FIG. 8 is a view illustrating the clamping portion of the photomask clamping device in a position of clamping a photomask according to another embodiment of the present application;

FIG. 9 is a view illustrating a working state of an outer sleeve body of the photomask clamping device driving a clamping member thereon to move out of a clamping hole according to another embodiment of the present application;

FIG. 10 is an enlarged view illustrating a structure of A in FIG. 9;

FIG. 11 is a view illustrating a working state of the outer sleeve body of the photomask clamping device driving an inner shaft body such that the clamping portion releases the photomask according to another embodiment of the present application;

FIG. 12 is an enlarged view illustrating a structure of B in FIG. 11;

FIG. 13 is a view illustrating a structure of the photomask clamping device clamping a photomask according to one embodiment of the present application;

FIG. 14 is a view illustrating a structure of the clamping portion according to one embodiment of the present application;

FIG. 15 is a view illustrating a structure of the clamping portion according to another embodiment of the present application; and

FIG. 16 is a view illustrating a structure of the clamping portion according to a further embodiment of the present application.

Reference numerals: 10. clamping assembly; 11. push-pull rod; 111. outer sleeve body; 112. inner shaft body; 113. first abutting portion; 114. second abutting portion; 115. turning block; 12. clamping member; 13. clamping portion; 131. clamping opening; 132. clamping plate; 133. bolt; 134. nut; 14. second drive gear; 15. second rack; 20. frame body; 21. side; 211. clamping hole; 22. connecting portion; 23. guide rod; 231. guide groove; 30. handle; 31. hollow chamber; 32. slot; 33. movement opening; 40. photomask; 50. first drive mechanism; 51. first drive shaft; 52. first bevel gear; 53. second drive shaft; 54. second bevel gear; 55. first drive gear; 56. first rack; 57. micro-motor; and 58. push member.

### DETAILED DESCRIPTION

To make the above objectives, features and advantages of the present application more comprehensible, the specific implementations of the present application are described in detail below with reference to the drawings. Many details are provided in the following description in order for a thorough understanding of the present application. However, the present application may be implemented in many other ways other than those described herein, and those skilled in the art may make similar improvements without departing from the connotation of the present application. Therefore, the present application is not limited to the specific embodiments disclosed below.

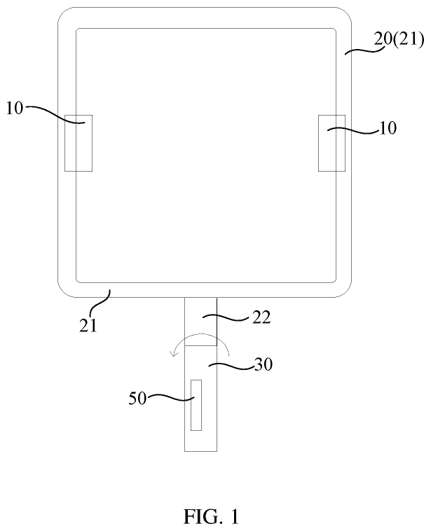

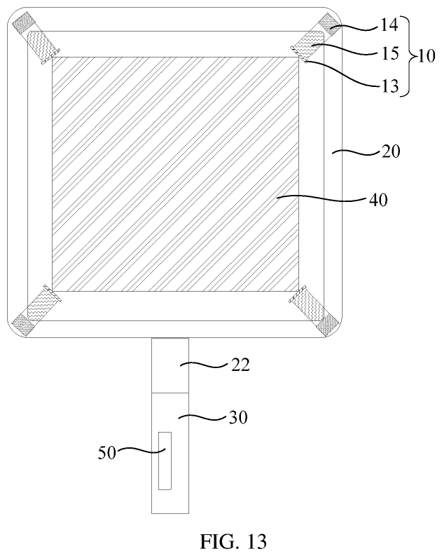

Referring to FIGS. 1 and 13, FIG. 1 is a view illustrating a structure of a photomask 40 clamping device according to one embodiment of the present application, and FIG. 13 is a view illustrating a structure of the photomask 40 clamping device clamping a photomask 40 according to a further embodiment of the present application. One embodiment of the present application provides a photomask 40 clamping device. The photomask 40 clamping device includes clamping assemblies 10, a frame body 20 and a handle 30. The clamping assemblies 10 are provided on the frame body 20, and the clamping assemblies 10 are used to clamp sides of a photomask 40. A connecting portion 22 is provided in the middle of one side 21 of the frame body 20. The handle 30 is rotatably connected to the connecting portion 22, and the handle 30 is provided with a first drive mechanism 50. The first drive mechanism 50 is connected to the connecting portion 22, and the first drive mechanism 50 is used to drive the connecting portion 22 to rotate.

In the photomask 40 clamping device, when it is necessary to deal with a problem on the surface of a photomask 40, the clamping assemblies 10 are used to clamp sides of the photomask 40, and the handle 30 is held in hand to take the photomask 40 out of a container through the clamping device. Then, with a central axis of the handle 30 as a center of rotation, the first drive mechanism 50 drives the connecting portion 22 to rotate, thereby flipping the frame body 20 and the photomask 40 on the frame body 20 from a glass surface to a pellicle surface. There is no need for a worker holding the handle 30 to rotate the operator's wrist to flip the frame body 20 and the photomask 40 thereon. Therefore, it is convenient to adjust the flip position of the photomask 40. Under the drive action of the first drive mechanism 50, the frame body 20 and the photomask 40 are flipped stably, and the photomask is not easily scratched.

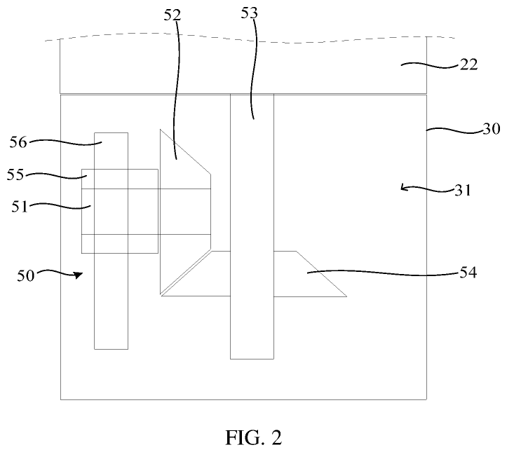

Referring to FIGS. 1 and 2, FIG. 2 is a view illustrating an internal structure of the handle 30 of the photomask 40 clamping device according to one embodiment of the present application. Further, the handle 30 is provided with a hollow chamber 31. The first drive mechanism 50 includes a first drive shaft 51, a first bevel gear 52, a second drive shaft 53, a second bevel gear 54 and a first drive gear 55. The first drive shaft 51 is rotatably provided on the handle 30. The first bevel gear 52 is coaxially and fixedly provided on the first drive shaft 51, and is located in the hollow chamber 31. The second drive shaft 53 is rotatably connected to the handle 30, and the second drive shaft 53 is coaxially connected to the connecting portion 22. The second bevel gear 54 is coaxially and fixedly provided on the second drive shaft 53, and is located in the hollow chamber 31. The second bevel gear 54 meshes with the first bevel gear 52. The first drive gear 55 is coaxially and fixedly provided on the first drive shaft 51. In this way, when the first drive gear 55 is driven to rotate, the rotation of the first drive gear 55 drives the first drive shaft 51 to rotate. The first drive shaft 51 drives the first bevel gear 52 thereon to rotate. The first bevel gear 52 drives the second bevel gear 54 to rotate. The second bevel gear 54 drives the second drive shaft 53 to rotate. Correspondingly, through the connecting portion 22, the second drive shaft 53 drives the frame body 20 and the photomask 40 thereon to flip around an axis of the connecting portion 22. That is, by manually pushing the first drive gear 55, the first drive gear 55 is rotated, and the photomask 40 is simultaneously driven to flip. This facilitates the adjustment of a flip position of the photomask 40. Under the drive action of the first drive mechanism 50, the frame body 20 and the photomask 40 are flipped stably, and the photomask is not easily scratched.

Referring to FIGS. 1 and 2, specifically, the first drive mechanism 50 further includes a first rack 56 that is movable on an outer surface of the handle 30. The first rack 56 and the first drive gear 55 mesh with each other. When the handle 30 is held in hand, the first rack 56 is pushed along an axial direction of the connecting portion 22, such that the first drive gear 55 is driven to rotate by the first rack 56. When the first drive gear 55 rotates, the photomask 40 is flipped. The photomask 40 can be flipped without directly rotating the operator's wrist as done conventionally, such that the photomask is not easily scratched.

In an optional solution, the first drive mechanism 50 may not be provided with the first drive shaft 51, the first bevel gear 52, the second bevel gear 54 and the first drive gear 55. Instead, the first drive mechanism is provided with the second drive shaft 53, and a push wheel is coaxially and fixedly provided on the second drive shaft 53. Further, the first drive mechanism 50 includes the second drive shaft 53 and the push wheel. The second drive shaft 53 is rotatably connected to the handle 30, and the second drive shaft 53 is coaxially connected to the connecting portion 22. The push wheel is coaxially and fixedly provided on the second drive shaft 53. When the photomask 40 needs to be flipped, the handle 30 is held, and the push wheel is pushed by a finger. When the push wheel rotates, the frame body 20 and the photomask 40 thereon are flipped accordingly. That is, the photomask 40 can be flipped without directly rotating the operator's wrist as done conventionally, such that the photomask is not easily scratched.

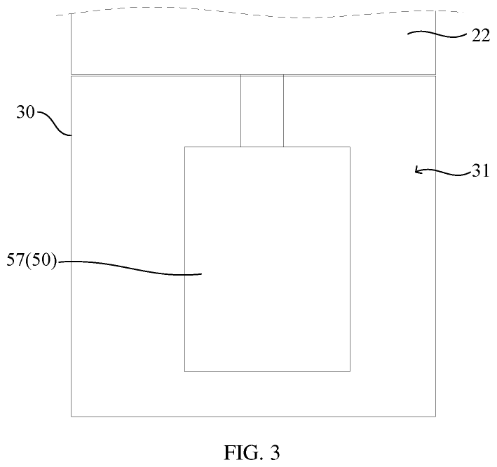

Referring to FIGS. 1 and 3, FIG. 3 is a view illustrating an internal structure of the handle 30 of the photomask 40 clamping device according to one embodiment of the present application. In the embodiment, the handle 30 is provided with a hollow chamber 31, and the first drive mechanism 50 includes a micro-motor 57 provided in the hollow chamber 31. A rotating shaft of the micro-motor 57 is coaxially and fixedly connected to the connecting portion 22.

Referring to FIGS. 1 and 3, the first drive mechanism 50 further includes a control element (not shown in the figure) provided on the handle 30. The control element is electrically connected to the micro-motor 57. Specifically, the control element is, for example, a switch button or a touch screen, etc. The control element correspondingly controls the action of the micro-motor 57, and the rotating shaft of the micro-motor 57 drives the connecting portion 22 to rotate, which accordingly drives the frame body 20 and the photomask 40 thereon to flip. The photomask 40 can be flipped without directly rotating the operator's wrist as done conventionally, such that the photomask is not easily scratched.

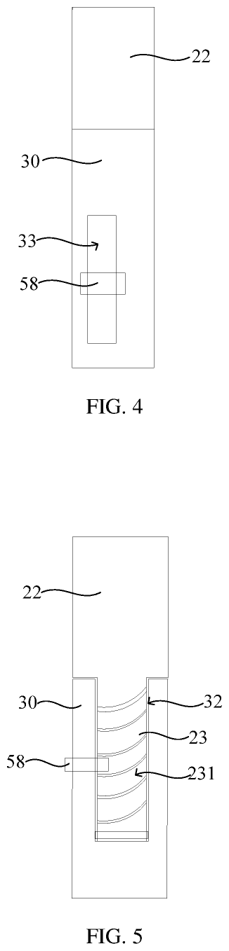

Referring to FIGS. 1, 4 and 5, FIG. 4 is a view illustrating a structure of the handle 30 of the photomask 40 clamping device according to one embodiment of the present application, and FIG. 5 is a view illustrating an internal structure of the handle 30 of the photomask 40 clamping device according to the third embodiment of the present application. In the third embodiment, the connecting portion 22 is provided with a guide rod 23. The handle 30 is provided with a slot 32 that is coaxial with the connecting portion 22. The guide rod 23 is rotatably provided in the slot 32, and a guide groove 231 is spirally provided on an outer wall of the guide rod 23. The handle 30 is provided with a movement opening 33 that is communicated with the slot 32. The first drive mechanism 50 includes a push member 58 that is movable along the movement opening 33. One end of the push member 58 is movably provided in the guide groove 231, and the other end of the push member 58 is located on an outer wall surface of the handle 30. When the photomask 40 needs to be flipped, the handle 30 is held in hand, and the push member 58 is pushed by a finger to move along the movement opening 33, such that an end of the push member 58 moves along the guide groove 231 simultaneously. Since the guide rod 23 is rotatably provided in the slot 32, when the end of the push member 58 moves along the guide groove 231, the guide rod 23 rotates. When the guide rod 23 rotates, it drives the connecting portion 22 to rotate, thereby correspondingly driving the frame body 20 and the photomask 40 thereon to flip. The photomask 40 can be flipped without directly rotating the operator's wrist as done conventionally, such that the photomask is not easily scratched.

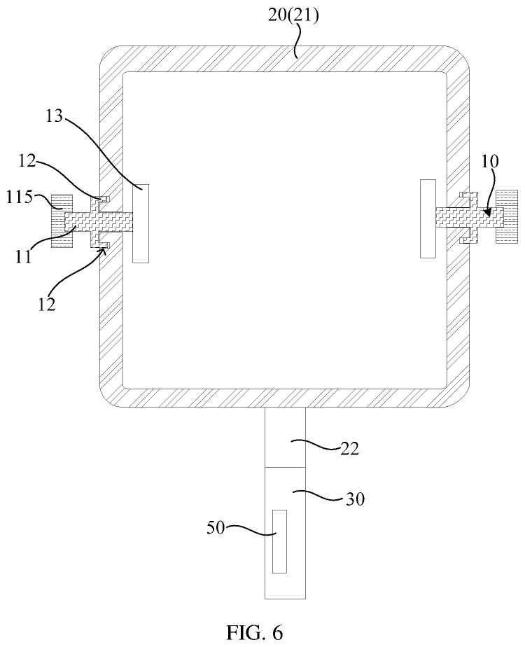

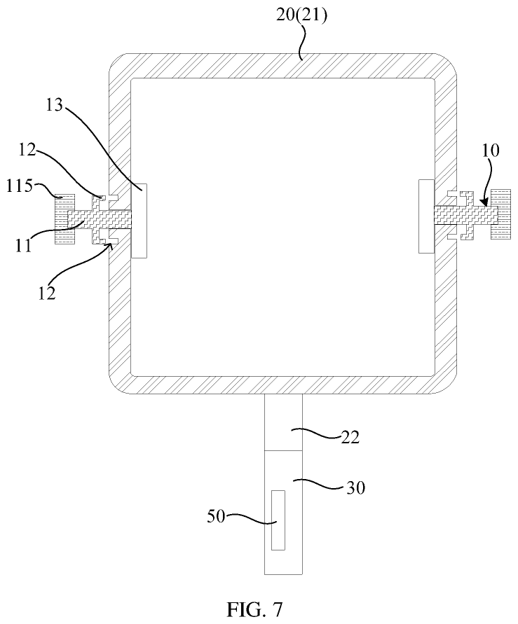

Referring to FIGS. 6 and 7, FIG. 6 is a view illustrating a clamping portion 13 of the photomask 40 clamping device in a position of clamping a photomask 40 according to the first embodiment of the present application, and FIG. 7 is a view illustrating the clamping portion 13 of the photomask 40 clamping device in a position of releasing the photomask 40 according to the first embodiment of the present application. In an embodiment, there are at least two clamping assemblies 10. The at least two clamping assemblies 10 are spaced apart on the frame body 20. The at least two clamping assemblies 10 simultaneously clamp at least two different parts of the photomask 40 so as to stably clamp the photomask 40. Specifically, there are, for example, two clamping assemblies 10. The two clamping assemblies 10 are respectively arranged on two opposite sides 21 of the frame body 20. That is, the two clamping assemblies 10 simultaneously clamp and fix two opposite sides of the photomask 40, so as to stably clamp photomask 40.

As shown in FIG. 13, in another embodiment, there may be, for example, four clamping assemblies 10. Specifically, the frame body 20 is, for example, a square frame body, that is, the frame body 20 is provided with four sides 21 and four corners. The four clamping assemblies 10 are, for example, respectively provided at the four corners of the frame body 20. In this way, the four clamping assemblies 10 respectively clamp four corners of the photomask 40, so as to stably clamp the photomask 40.

In another optional solution, there may also be one, three, five or six clamping assemblies 10, etc., which is not limited herein. In addition, the clamping position of the clamping assembly 10 on the photomask 40 is not limited, which depends on actual requirements.

Referring to FIGS. 6 and 7, in the first embodiment, the clamping assemblies 10 each include a push-pull rod 11, a clamping member 12 provided on an outer wall of the push-pull rod 11 and a clamping portion 13 connected to an end of the push-pull rod 11. The push-pull rod 11 is movably provided in the middle of the side 21, and a clamping hole 211 corresponding to the clamping member 12 are provided in the middle of the side 21. When the clamping portion 13 clamps a side of the photomask 40, the clamping member 12 is clamped and fixed in the clamping hole 211. When the photomask 40 needs to be clamped and fixed, the frame body 20 is placed on a periphery of the photomask 40. The push-pull rod 11 is pushed such that the clamping portion 13 connected to the push-pull rod 11 moves toward the side of the photomask 40 and clamps the side of the photomask 40. When the clamping portion 13 clamps the side of the photomask 40, the clamping member 12 is clamped and fixed in the clamping hole 211. When the photomask 40 needs to be removed from the frame body 20, the clamping member 12 is removed from the clamping hole 211. The push-pull rod 11 is pushed to cause the clamping portion 13 to move away from the side of the photomask 40, so as to release the side of the photomask 40.

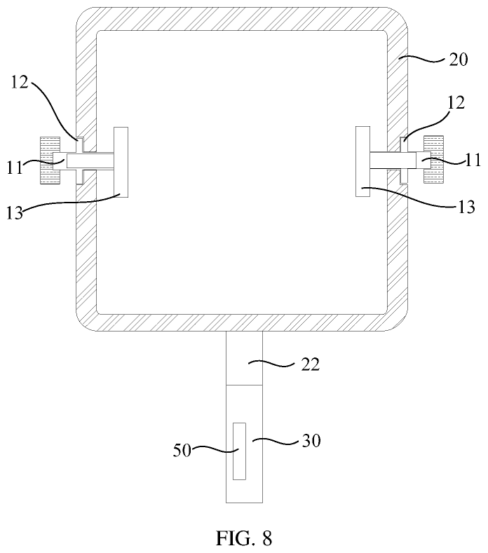

It should be noted that the specific shape and structure of the clamping member 12 and the clamping holes 211 are not limited herein, which depend on requirements. For example, as shown in FIGS. 6 and 7, the clamping holes 211 are in the form of a socket, and the clamping member 12 is designed to fit into the socket. For another example, as shown in FIGS. 8 to 13, the clamping holes 211 are in the form of a clamping slot, and the clamping member 12 is designed as a clamping block that fits into the clamping slot.

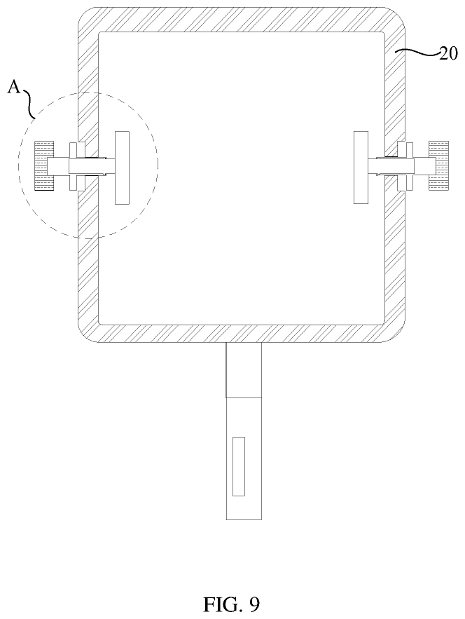

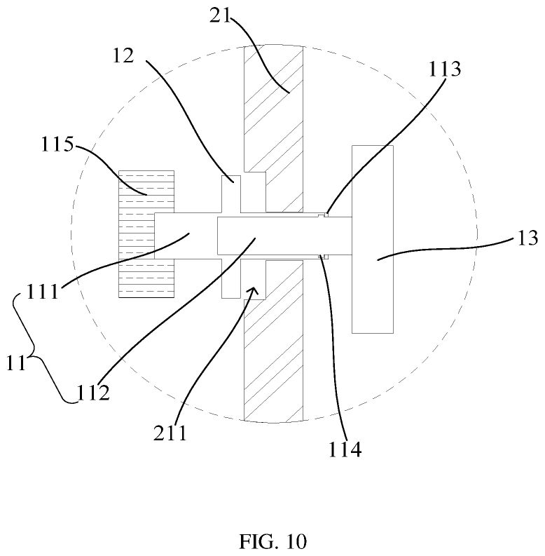

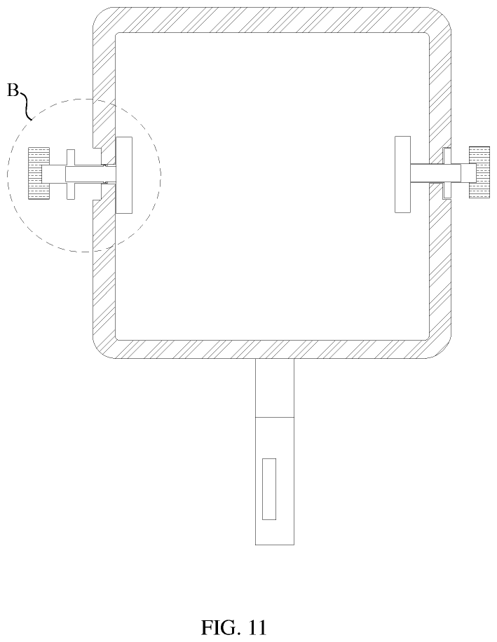

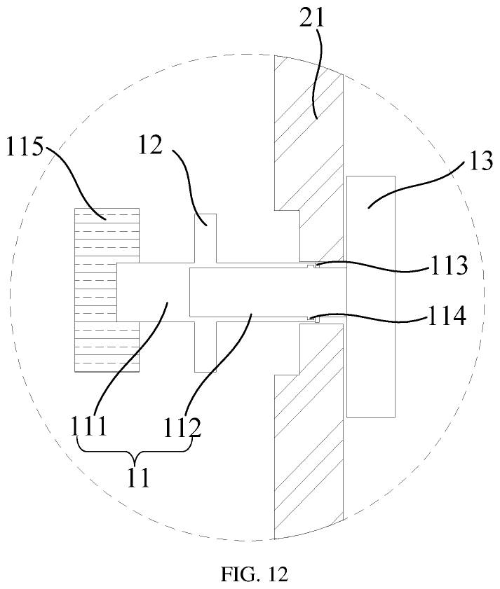

Referring to FIGS. 8 to 12, FIG. 8 is a view illustrating the clamping portion 13 of the photomask 40 clamping device in a position of clamping a photomask 40 according to the second embodiment of the present application; FIG. 9 is a view illustrating a working state of an outer sleeve body 111 of the photomask 40 clamping device driving a clamping member 12 thereon to move out of a clamping hole 211 according to the second embodiment of the present application; FIG. 10 is an enlarged view illustrating a structure of A in FIG. 9; FIG. 11 is a view illustrating a working state of the outer sleeve body 111 of the photomask 40 clamping device drive an inner shaft body 112 such that the clamping portion 13 releases the photomask 40 according to the second embodiment of the present application; and FIG. 12 is an enlarged view illustrating a structure of B in FIG. 11. In this embodiment, there are two clamping assemblies 10, and the two clamping assemblies 10 are correspondingly arranged in the middle of two opposite sides 21 of the frame body 20. The push-pull rod 11 includes an outer sleeve body 111 and an inner shaft body 112 nested inside the outer sleeve body 111. An inner wall of the outer sleeve body 111 is provided with a spline shaft. An outer wall of the inner shaft body 112 is provided with a spline groove that is adapted to the spline shaft. The spline shaft is movably provided in the spline groove along an axial direction of the inner shaft body 112. An outer wall of the outer sleeve body 111 is connected to the clamping member 12, and an end of the inner shaft body 112 is connected to the clamping portion 13. A first abutting portion 113 is provided on an inner wall of an end of the outer sleeve body 111 close to the clamping portion 13. An outer wall of the inner shaft body 112 is provided with a second abutting portion 114 abuttingly fitting with the first abutting portion 113. The first abutting portion 113 is used to drive the second abutting portion 114 to move in a direction away from the photomask 40. There are at least two clamping holes 211 provided in the middle of each side 21. The at least two clamping holes 211 are arranged on two sides of the push-pull rod 11. The clamping member 12 is able to be clamped and fixed in any one of the clamping holes 211. When the photomask 40 needs to be driven to flip up and down around a horizontal axis of the frame body 20, the outer sleeve body 111 is moved in a direction away from the photomask 40. The outer sleeve body 111 drives the clamping member 12 provided thereon to be pulled out from one of the clamping holes 211. Then the outer sleeve body 111 is driven to rotate, and the inner shaft body 112 is driven to rotate when the outer sleeve body 111 rotates. When the inner shaft body 112 rotates, the photomask 40 clamped by the clamping portion 13 is driven to be flipped, for example, by 180°. After the position of the photomask 40 is adjusted in place, the outer sleeve body 111 is moved in a direction toward the photomask 40, and the outer sleeve body 111 drives the clamping member 12 provided thereon to be clamped and fixed into the other clamping hole 211.

Referring to FIGS. 6 to 8, in an embodiment, a turning block 115 is provided on an end of the push-pull rod 11 away from the clamping portion 13. When a force is applied to the turning block 115, the turning block 115 drives the push-pull rod 11 to rotate, which is convenient to operate.

Referring to FIG. 13, in an embodiment, the clamping assembly 10 includes a gear 14 rotatably provided on the frame body 20, a first rack 15 movably provided on the frame body 20 and a clamping portion 13 connected to an end of the second rack 15. The gear 14 and the second rack 15 mesh with each other. The clamping portion 13 is used to clamp a side of the photomask 40. By driving the gear 14 to rotate, the gear 14 drives the second rack 15 to move. When the second rack 15 moves, the clamping portion 13 connected to the end of the second rack is driven to move to the side of the photomask 40. In this way, the clamping portion can clamp the side of the photomask 40 of different sizes, and the clamping of the photomask 40 is stable and convenient.

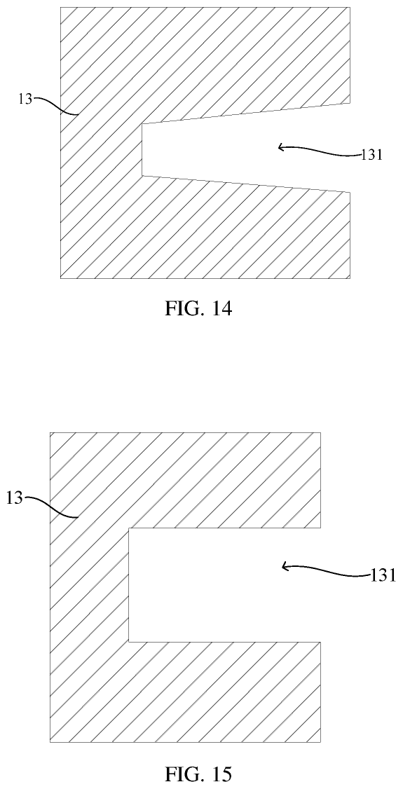

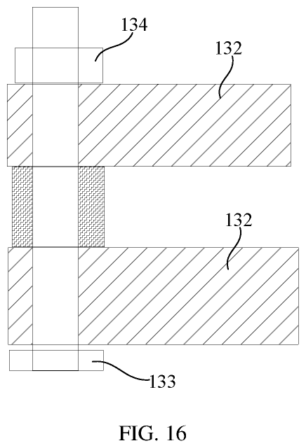

Referring to FIGS. 14 to 16, FIGS. 14 to 16 illustrate three different structures of the clamping portion 13, respectively. In an embodiment, the clamping portion 13 is provided with a clamping opening 131, and a distance between two opposite clamping wall surfaces of the clamping opening 131 is gradually reduced or remains unchanged. Alternatively, the clamping portion 13 includes two clamping plates 132, a bolt 133 connecting the two clamping plates 132 and a nut 134 provided on the bolt 133.

Further, the clamping portion 13 is a rubber strip, a silicone strip, a polyurethane strip, a polyethylene strip or a soft wood strip. When the clamping portion 13 is a rubber strip, a silicone strip, a polyurethane strip, a polyethylene strip or a soft wood strip, the clamping portion 13 has elasticity and flexibility, and causes little damage to the photomask when clamping a side of the photomask. Of course, it is understandable that the clamping portion 13 may also be made of other type of material, depending on actual requirements, which is not limited herein.

It should be noted that the connecting portion 22 may be a part of the frame body 20, that is, the connecting portion 22 and other parts of the frame body 20 are integrally formed. The connecting portion 22 may also be an independent component that is separable from other parts of the frame body 20, that is, it may be formed independently and then combined with other parts of the frame body 20 into a whole. As shown in FIG. 1, in the embodiment, the connecting portion 22 is a part of the frame body 20 that is integrally formed.

The technical characteristics of the above embodiments can be employed in arbitrary combinations. In an effort to provide a concise description of these embodiments, all possible combinations of all technical characteristics of the embodiments may not be described. However, these combinations of technical characteristics should be construed as disclosed in the description as long as no contradiction occurs.

Only several embodiments of the present application are described in detail above, but they should not therefore be construed as limiting the scope of the present application. It should be noted that those of ordinary skill in the art can further make variations and improvements without departing from the concept of the present application. These variations and improvements all fall within the protection scope of the present application. Therefore, the protection scope of the present application should be subject to the protection scope defined by the claims.

It should be noted that, in the description of the present application, the terms such as “central”, “longitudinal”, “transverse”, “long”, “wide”, “thick”, “upper”, “lower”, “front”, “back”, “left”, “right”, “vertical”, “horizontal”, “top”, “bottom”, “inner”, “outer”, “clockwise”, “anticlockwise”, “axial”, “radial” and “circumferential” are used to indicate orientations shown in the drawings. It should be noted that these terms are merely intended to facilitate a simple description of the present application, rather than to indicate or imply that the mentioned apparatus or elements must have the specific orientation or be constructed and operated in the specific orientation. Therefore, these terms may not be construed as a limitation to the present application.

Moreover, the terms such as “first” and “second” are used only for the purpose of description and should not be construed as indicating or implying a relative importance, or implicitly indicating a quantity of indicated technical features. Therefore, features defined by “first” and “second” may explicitly or implicitly include at least one of the features. In description of the present application, “a plurality of” means at least two, for example, two or three, unless otherwise clearly and specifically limited.

In the present application, unless otherwise clearly specified, the terms such as “mounting”, “interconnection”, “connection” and “fixation” are intended to be understood in a broad sense. For example, the “connection” may be a fixed connection, removable connection or integral connection; may be a mechanical connection or electrical connection; may be a direct connection or indirect connection using a medium; and may be a communication or interaction between two elements. Those of ordinary skill in the art may understand the specific meanings of the above terms in the present application based on the specific situation.

In the present application, unless otherwise explicitly specified, when it is described that a first feature is “above” or “below” a second feature, it indicates that the first and second features are in direct contact or the first and second features are in indirect contact through an intermediate feature. In addition, when it is described that the first feature is “over”, “above” and “on” the second feature, it indicates that the first feature is directly or obliquely above the second feature, or simply indicates that an altitude of the first feature is higher than that of the second feature. When it is described that a first feature is “under”, “below” or “beneath” a second feature, it indicates that the first feature is directly or obliquely under the second feature or simply indicates that the first feature is lower than the second feature.

It should be noted that when a component is “fixed” or “provided” on the other component, the component may be fixed on the other component directly or via an intermediate component. When a component is connected with the other component, the component may be connected with the other component directly or via an intermediate component. The terms “vertical”, “horizontal”, “upper”, “lower”, “left”, “right” and other similar expressions used herein are for illustrative purposes only, rather than to mean the only implementation.

What is claimed is:

1. A photomask clamping device, comprising:
clamping assemblies and a frame body, wherein the clamping assemblies are provided on the frame body; the clamping assemblies are used to clamp sides of a photomask; and a connecting portion is provided in the middle of one side of the frame body; and
a handle, wherein the handle is rotatably connected to the connecting portion; the handle is provided with a first drive mechanism; the first drive mechanism is connected to the connecting portion; and the first drive mechanism is used to drive the connecting portion to rotate.

2. The photomask clamping device according to claim 1, wherein the handle is provided with a hollow chamber; the first drive mechanism comprises a first drive shaft, a first bevel gear, a second drive shaft, a second bevel gear and a first drive gear; the first drive shaft is rotatably provided on the handle; the first bevel gear is coaxially and fixedly provided on the first drive shaft, and is located in the hollow chamber; the second drive shaft is rotatably connected to the handle, and the second drive shaft is coaxially connected to the connecting portion; the second bevel gear is coaxially and fixedly provided on the second drive shaft, and is located in the hollow chamber; the second bevel gear meshes with the first bevel gear; and the first drive gear is coaxially and fixedly provided on the first drive shaft.

3. The photomask clamping device according to claim 1, wherein the first drive mechanism comprises a second drive shaft and a push wheel; the second drive shaft is rotatably connected to the handle, and the second drive shaft is coaxially connected to the connecting portion; and the push wheel is coaxially and fixedly provided on the second drive shaft.

4. The photomask clamping device according to claim 1, wherein the handle is provided with a hollow chamber; the first drive mechanism comprises a micro-motor provided in the hollow chamber; and a rotating shaft of the micro-motor is coaxially and fixedly connected to the connecting portion.

5. The photomask clamping device according to claim 4, wherein the first drive mechanism further comprises a control element provided on the handle; and the control element is electrically connected to the micro-motor.

6. The photomask clamping device according to claim 5, wherein the control element is a switch button or a touch screen.

7. The photomask clamping device according to claim 1, wherein the connecting portion is provided with a guide rod; the handle is provided with a slot that is coaxial with the connecting portion; the guide rod is rotatably provided in the slot; a guide groove is spirally provided on an outer wall of the guide rod; the handle is provided with a movement opening that is communicated with the slot; the first drive mechanism comprises a push member that is movable along the movement opening; and one end of the push member is movably provided in the guide groove, and the other end of the push member is located on an outer wall surface of the handle.

8. The photomask clamping device according to claim 1, wherein there are at least two clamping assemblies, and the at least two clamping assemblies are spaced apart on the frame body.

9. The photomask clamping device according to claim 8, wherein the clamping assemblies each comprise a push-pull rod, a clamping member provided on an outer wall of the push-pull rod and a clamping portion connected to an end of the push-pull rod; the push-pull rod is movably provided in the middle of a side of the frame body; a clamping hole corresponding to the clamping member are provided in the middle of the side of the frame body; and when the clamping portion clamps a side of the photomask, the clamping member is clamped and fixed in the clamping hole.

10. The photomask clamping device according to claim 9, wherein there are two clamping assemblies, and the two clamping assemblies are correspondingly arranged in the middle of two opposite sides of the frame body; the push-pull rod comprises an outer sleeve body and an inner shaft body nested inside the outer sleeve body; an inner wall of the outer sleeve body is provided with a spline shaft; an outer wall of the inner shaft body is provided with a spline groove that is adapted to the spline shaft; the spline shaft is movably provided in the spline groove along an axial direction of the inner shaft body; an outer wall of the outer sleeve body is connected to the clamping member, and an end of the inner shaft body is connected to the clamping portion; a first abutting portion is provided on an inner wall of an end of the outer sleeve body close to the clamping portion; an outer wall of the inner shaft body is provided with a second abutting portion that abuttingly fitting with the first abutting portion; the first abutting portion is used to drive the second abutting portion to move in a direction away from the photomask; there are at least two clamping holes provided in the middle of each side of the frame body; the at least two clamping holes are arranged on two sides of the push-pull rod; and the clamping member is able to be clamped and fixed in any one of the clamping holes.

11. The photomask clamping device according to claim 10, wherein a turning block is provided on an end of the push-pull rod away from the clamping portion.

12. The photomask clamping device according to claim 8, wherein the clamping assemblies each comprise a second drive gear rotatably provided on the frame body, a second rack movably provided on the frame body and a clamping portion connected to an end of the second rack; the second drive gear and the second rack mesh with each other; and the clamping portion is used to clamp a side of the photomask.

13. The photomask clamping device according to claim 8, wherein the clamping portion is provided with a clamping opening, and a distance between two opposite clamping wall surfaces of the clamping opening is gradually reduced or remains unchanged.

14. The photomask clamping device according to claim 8, wherein the clamping portion comprises two clamping plates, a bolt connecting the two clamping plates and a nut provided on the bolt.

15. The photomask clamping device according to claim 8, wherein the clamping portion is a rubber strip, a silicone strip, a polyurethane strip, a polyethylene stripe, or a soft wood strip.
